(19) United States
(12) Patent Application Publication
(10) Pub. No.: US 2026/0248002 A1
(43) Pub. Date: Aug. 20, 2026

(54) PACKAGE STRUCTURE

(71) Applicant: Advanced Semiconductor Engineering, Inc., Kaohsiung (TW)

(72) Inventors: Cheng-Lan LIN, Kaohsiung (TW); Chia-Yin CHIANG, Kaohsiung (TW); Guo-Cheng LIAO, Kaohsiung (TW)

(73) Assignee: Advanced Semiconductor Engineering, Inc., Kaohsiung (TW)

(21) Appl. No.: 19/059,077

(22) Filed: Feb. 20, 2025

(51) Int. Cl. H01L 23/538; H01L 21/48; H01L 23/00; H01L 23/498; H01L 25/07

(52) U.S. Cl. CPC H10W 70/65; H10W 70/05; H10W 70/611; H10W 90/00; H10W 74/15; H10W 90/701; H10W 90/724; H10W 90/734

(57) ABSTRACT

A package structure includes a substrate, a redistribution layer (RDL) structure, a first electronic component and a second electronic component. The redistribution layer (RDL) structure is disposed on the substrate. The first electronic component is disposed over the redistribution layer (RDL) structure. The second electronic component is disposed over the redistribution layer (RDL) structure. The first electronic component is electrically communicated with the second electronic component through the substrate and the redistribution layer (RDL) structure. A number of input/output (I/O) count of the redistribution layer (RDL) structure is less than a number of input/output (I/O) count of the substrate.

### BACKGROUND

### 1. Field of the Disclosure

The present disclosure relates to a package structure and a method for manufacturing a package structure, and to a package structure including at least one electronic component.

### 2. Description of the Related Art

Along with the rapid development in electronics industry and the progress of semiconductor processing technologies, semiconductor chips are integrated with an increasing number of electronic components to achieve improved electrical performance and additional functions. Accordingly, the semiconductor chips are provided with more input/output (I/O) connections. To manufacture semiconductor packages including semiconductor chips with an increased number of I/O connections, circuit layers of semiconductor substrates used for carrying the semiconductor chips may correspondingly increase in size. Thus, a thickness and a warpage of the semiconductor substrate may correspondingly increase, and a yield of the semiconductor substrate may decrease.

### SUMMARY

In some embodiments, a package structure includes a substrate, a redistribution layer (RDL) structure, a first electronic component and a second electronic component. The redistribution layer (RDL) structure is disposed on the substrate. The first electronic component is disposed over the redistribution layer (RDL) structure. The second electronic component is disposed over the redistribution layer (RDL) structure. The first electronic component is electrically communicated with the second electronic component through the substrate and the redistribution layer (RDL) structure. A number of input/output (I/O) count of the redistribution layer (RDL) structure is less than a number of input/output (I/O) count of the substrate.

In some embodiments, a package structure includes a low-density conductive structure, a high-density conductive structure, a first electronic component and a second electronic component. The low-density conductive structure includes a plurality of circuit layers and a plurality of inner vias electrically connecting the plurality of circuit layers. The high-density conductive structure is disposed on the low-density conductive structure, and includes a plurality of circuit layers and a plurality of inner vias electrically connecting the plurality of circuit layers. The first electronic component is disposed over the high-density conductive structure. The second electronic component is disposed over the high-density conductive structure and spaced apart from the first electronic component. The plurality of inner vias of the low-density conductive structure and the plurality of inner vias of the high-density conductive structure taper toward the first electronic component and the second electronic component.

In some embodiments, a package structure includes a substrate, a redistribution layer (RDL) structure, a first electronic component and a second electronic component. The substrate includes a first circuit layer and a second circuit layer. The redistribution layer (RDL) structure is disposed on the substrate, and includes a signal transmission layer. The first electronic component is disposed over the signal transmission layer. The first electronic component includes a first region. The second electronic component is disposed over the signal transmission layer. The first region of the first electronic component is electrically connected to second electronic component by a first signal transmission path passing through the signal transmission layer, a second signal transmission path passing through the first circuit layer, and a third signal transmission path passing through the second circuit layer. An entire length of the first signal transmission path is shorter than an entire length of the second signal transmission path.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of a package structure according to some embodiments of the present disclosure.

FIG. 2 illustrates a cross-sectional view of a plurality of signal transmission paths of the package structure of FIG. 1.

FIG. 2A illustrates a cross-sectional view of a plurality of signal transmission paths of a package structure according to some embodiments of the present disclosure.

FIG. 3 illustrates a top view of the first electronic component and the second electronic component of the package structure of FIG. 1.

FIG. 4 illustrates a layout of the first circuit layer of the second circuit pattern structure of the package structure of FIG. 1.

FIG. 5 illustrates a layout of the first circuit layer of the first circuit pattern structure of the package structure of FIG. 1.

FIG. 6 illustrates a layout of the third circuit layer of the first circuit pattern structure of the package structure of FIG. 1.

FIG. 7 illustrates one or more stages of an example of a method for manufacturing a package structure according to some embodiments of the present disclosure.

FIG. 8 illustrates one or more stages of an example of a method for manufacturing a package structure according to some embodiments of the present disclosure.

FIG. 9 illustrates one or more stages of an example of a method for manufacturing a package structure according to some embodiments of the present disclosure.

FIG. 10 illustrates one or more stages of an example of a method for manufacturing a package structure according to some embodiments of the present disclosure.

FIG. 11 illustrates one or more stages of an example of a method for manufacturing a package structure according to some embodiments of the present disclosure.

FIG. 12 illustrates one or more stages of an example of a method for manufacturing a package structure according to some embodiments of the present disclosure.

FIG. 13 illustrates one or more stages of an example of a method for manufacturing a package structure according to some embodiments of the present disclosure.

FIG. 14 illustrates one or more stages of an example of a method for manufacturing a package structure according to some embodiments of the present disclosure.

FIG. 15 illustrates one or more stages of an example of a method for manufacturing a package structure according to some embodiments of the present disclosure.

FIG. 16 illustrates one or more stages of an example of a method for manufacturing a package structure according to some embodiments of the present disclosure.

FIG. 17 illustrates one or more stages of an example of a method for manufacturing a package structure according to some embodiments of the present disclosure.

FIG. 18 illustrates one or more stages of an example of a method for manufacturing a package structure according to some embodiments of the present disclosure.

FIG. 19 illustrates one or more stages of an example of a method for manufacturing a package structure according to some embodiments of the present disclosure.

FIG. 20 illustrates one or more stages of an example of a method for manufacturing a package structure according to some embodiments of the present disclosure.

FIG. 21 illustrates one or more stages of an example of a method for manufacturing a package structure according to some embodiments of the present disclosure.

FIG. 22 illustrates one or more stages of an example of a method for manufacturing a package structure according to some embodiments of the present disclosure.

FIG. 23 illustrates one or more stages of an example of a method for manufacturing a package structure according to some embodiments of the present disclosure.

FIG. 24 illustrates one or more stages of an example of a method for manufacturing a package structure according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

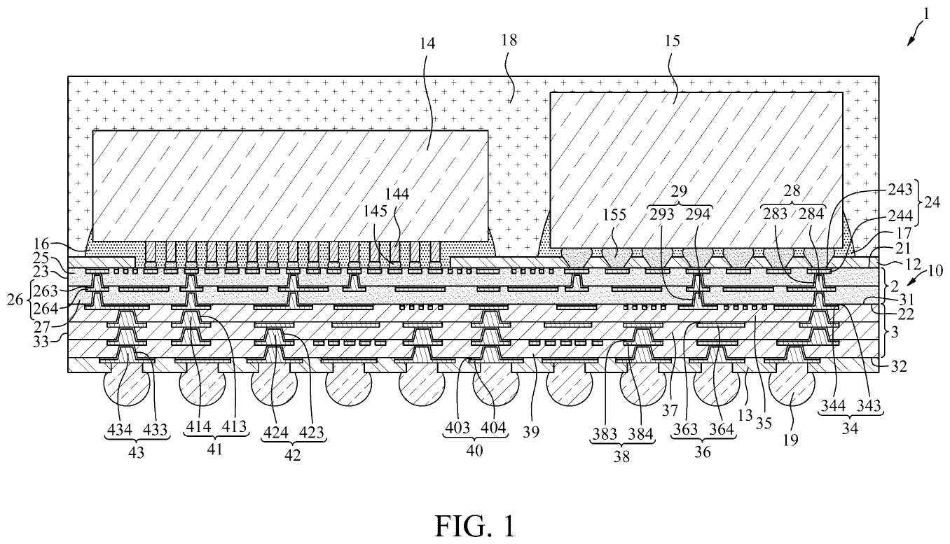

FIG. 1 illustrates a cross-sectional view of a package structure 1 according to some embodiments of the present disclosure. The package structure 1 may be also referred to as “an electronic package”, “semiconductor package structure” or “an electronic device”. The package structure 1 may include a first circuit pattern structure 3 (e.g., a substrate), a second circuit pattern structure 2 (e.g., a redistribution layer (RDL) structure), a first electronic component 14, a first underfill 16, a second electronic component 15, a second underfill 17, an encapsulant 18 and a plurality of external connectors 19.

The first circuit pattern structure 3 may be also referred to as “a substrate”, “a redistribution layer (RDL) structure”, “a lower substrate”, “a lower wiring structure”, “a lower stacked structure”, “a lower conductive structure”, “a low-density circuit pattern structure”, “a low-density substrate”, “a low-density wiring structure”, “a low-density stacked structure”, “a low-density conductive structure”, “a lower circuit pattern structure”, “a first substrate”, “a first wiring structure”, “a first stacked structure”, or “a first conductive structure”.

The first circuit pattern structure 3 may be formed on or directly built up on a second surface 22 (e.g., a bottom surface) of the second circuit pattern structure 2. The first circuit pattern structure 3 may include at least one dielectric layer (including, for example, a first dielectric layer 35, a second dielectric layer 37 and a third dielectric layer 39) and at least one circuit layer (including, for example, a first circuit layer 34, a second circuit layer 36, a third circuit layer 38 and a fourth circuit layer 40) in contact with the dielectric layer (e.g., the dielectric layers 35, 37, 39). In one embodiment, the first circuit pattern structure 3 may be similar to a coreless substrate, and may be in a wafer type, a panel type or a strip type. The first circuit pattern structure 3 may have a first surface 31 (e.g., a top surface), a second surface 32 (e.g., a bottom surface) opposite to the first surface 31 (e.g., the top surface), and a lateral surface 33 extending between the first surface 31 (e.g., the top surface) and the second surface 32 (e.g., the bottom surface).

The first circuit pattern structure 3 may include a plurality of dielectric layers (for example, the dielectric layers 35, 37, 39), a plurality of circuit layers (for example, the circuit layers 34, 36, 38, 40) and a plurality of inner vias (for example, the first inner via 41, the second inner via 42 and the third inner via 43). The dielectric layers 35, 37, 39 are stacked on one another. In one embodiment, a material of the first dielectric layer 35, the second dielectric layer 37 and the third dielectric layer 39 may be a passivation layer, and may include, or be formed from, a photoresist layer, a cured photosensitive material, a cured photoimageable dielectric (PID) material such as a polyamide (PA), an Ajinomoto build-up film (ABF), a bismaleimide-triazine (BT), a polypropylene (PP), a polyimide (PI), epoxy or polybenzoxazole (PBO), or a combination of two or more thereof. In one embodiment, a first material of the dielectric layers 35, 37, 39 of the first circuit pattern structure 3 includes a first resin material with fiber such as glass fiber. For example, the first material of the dielectric layers 35, 37, 39 of the first circuit pattern structure 3 may include prepreg material.

In addition, each of the circuit layers 34, 36, 38, 40 may include a plurality of traces and a plurality of pads. The circuit layers 34, 36, 38, 40 are electrically connected to one another through the inner vias 41, 42, 43. The first circuit layer 34 may be a fan-out circuit layer, and may be directly disposed on the second surface 22 (e.g., the bottom surface) of the second circuit pattern structure 2. A line width/line space (L/S) of the first circuit layer 34 may be less than or equal to 18 μm/18 μm, or less than or equal to 17 μm/17 μm, or less than or equal to 15 μm/15 μm, or less than or equal to 10 μm/15 μm, or less than or equal to 7 μm/9 μm, or less than or equal to 9 μm/12 μm. In one embodiment, the first circuit layer 34 may be also referred to as “a third circuit layer” or “a second signal transmission layer”. In one embodiment, the first circuit layer 34 may include a seed layer 343 and a conductive metal material 344 (e.g., copper) disposed on the seed layer 343. The first dielectric layer 35 may cover the first circuit layer 34. Thus, the first circuit layer 34 may be embedded in the first dielectric layer 35. A top surface of the first circuit layer 34 may be substantially aligned with a top surface of the first dielectric layer 35. Thus, the top surface of the first circuit layer 34 and the top surface of the first dielectric layer 35 may directly contact the second surface 22 (e.g., the bottom surface) of the second circuit pattern structure 2. The first dielectric layer 35 ma be also referred to as “a third dielectric layer”.

The second circuit layer 36 may be a fan-out circuit layer, and a line width/line space (L/S) of the second circuit layer 36 may be less than or equal to 18 μm/18 μm, or less than or equal to 17 μm/17 μm, or less than or equal to 15 μm/15 μm, or less than or equal to 10 μm/15 μm, or less than or equal to 7 μm/9 μm, or less than or equal to 9 μm/12 μm. In one embodiment, the line width/line space (L/S) of the second circuit layer 36 may be equal to or greater than the line width/line space (L/S) of the first circuit layer 34. In one embodiment, the second circuit layer 36 may be a grounding layer. The second circuit layer 36 may be also referred to as “a first grounding layer”, or “a second grounding layer” or “a fourth circuit layer”. In one embodiment, the second circuit layer 36 may include a seed layer 363 and a conductive metal material 364 (e.g., copper) disposed on the seed layer 363. The second circuit layer 36 may be formed or disposed on the bottom surface of the first dielectric layer 35.

The first inner via 41 may be disposed in an opening of the first dielectric layer 35, and extend through the first dielectric layer 35 to contact and electrically connect the first circuit layer 34 and the second circuit layer 36. The first inner via 41 may include a seed layer 413 and a conductive metal material 414 (e.g., copper) disposed on the seed layer 413. In some embodiments, the second circuit layer 36 and the first inner via 41 may be formed integrally and concurrently. Thus, the seed layer 363 and the seed layer 413 may be the same layer. The conductive metal material 364 and the conductive metal material 414 may be the same layer. In addition, the first inner via 41 may taper upward. Thus, the first inner via 41 may taper toward the first electronic component 14 and the second electronic component 15. In one embodiment, the first inner via 41 may be also referred to as “a third inner via”.

The second dielectric layer 37 may cover the second circuit layer 36. Thus, the second circuit layer 36 may be embedded in the second dielectric layer 37. A top surface of the second circuit layer 36 may be substantially coplanar with a top surface of the second dielectric layer 37. The second dielectric layer 37 may be also referred to as “a fourth dielectric layer”.

The third circuit layer 38 may be a fan-out circuit layer, and a line width/line space (L/S) of the third circuit layer 38 may be less than or equal to 18 μm/18 μm, or less than or equal to 17 μm/17 μm, or less than or equal to 15 μm/15 μm, or less than or equal to 10 μm/15 μm, or less than or equal to 7 μm/9 μm, or less than or equal to 9 μm/12 μm. In one embodiment, the line width/line space (L/S) of the third circuit layer 38 may be equal to or greater than the line width/line space (L/S) of the first circuit layer 34 and/or the second circuit layer 36. In one embodiment, the third circuit layer 38 may be also referred to as “a second circuit layer”, or “a fifth circuit layer” or “a third signal transmission layer”. In one embodiment, the third circuit layer 38 may include a seed layer 383 and a conductive metal material 384 (e.g., copper) disposed on the seed layer 383. The third circuit layer 38 may be formed or disposed on the bottom surface of the second dielectric layer 37.

The second inner via 42 may be disposed in an opening of the second dielectric layer 37, and extend through the second dielectric layer 37 to contact and electrically connect the second circuit layer 36 and the third circuit layer 38. The second inner via 42 may include a seed layer 423 and a conductive metal material 424 (e.g., copper) disposed on the seed layer 423. In some embodiments, the third circuit layer 38 and the second inner via 42 may be formed integrally and concurrently. Thus, the seed layer 383 and the seed layer 423 may be the same layer. The conductive metal material 384 and the conductive metal material 424 may be the same layer. In addition, the second inner via 42 may taper upward. Thus, the second inner via 42 may taper toward the first electronic component 14 and the second electronic component 15. In one embodiment, the second inner via 42 may be also referred to as “a fourth inner via”.

The third dielectric layer 39 may cover the third circuit layer 38. Thus, the third circuit layer 38 may be embedded in the third dielectric layer 39. A top surface of the third circuit layer 38 may be substantially coplanar with a top surface of the third dielectric layer 39. The third dielectric layer 39 may be also referred to as “a fifth dielectric layer”.

The fourth circuit layer 40 may be a fan-out circuit layer, and a line width/line space (L/S) of the fourth circuit layer 40 may be less than or equal to 18 μm/18 μm, or less than or equal to 17 μm/17 μm, or less than or equal to 15 μm/15 μm, or less than or equal to 10 μm/15 μm, or less than or equal to 7 μm/9 μm, or less than or equal to 9 μm/12 μm. In one embodiment, the line width/line space (L/S) of the fourth circuit layer 40 may be equal to or greater than the line width/line space (L/S) of the first circuit layer 34 and/or the second circuit layer 36 and/or the third circuit layer 38. In one embodiment, the fourth circuit layer 40 may be also referred to as “a third circuit layer”, or “a sixth circuit layer”. In one embodiment, the fourth circuit layer 40 may include a seed layer 403 and a conductive metal material 404 (e.g., copper) disposed on the seed layer 403. The fourth circuit layer 40 may b e formed or disposed on the bottom surface of the third dielectric layer 39.

The third inner via 43 may be disposed in an opening of the third dielectric layer 39, and extend through the third dielectric layer 39 to contact and electrically connect the third circuit layer 38 and the fourth circuit layer 40. The third inner via 43 may include a seed layer 433 and a conductive metal material 434 (e.g., copper) disposed on the seed layer 433. In some embodiments, the fourth circuit layer 40 and the third inner via 43 may be formed integrally and concurrently. Thus, the seed layer 403 and the seed layer 433 may be the same layer. The conductive metal material 404 and the conductive metal material 434 may be the same layer. In addition, the third inner via 43 may taper upward. Thus, the third inner via 43 may taper toward the first electronic component 14 and the second electronic component 15. In one embodiment, the third inner via 43 may be also referred to as “a fifth inner via”.

The second circuit pattern structure 2 may be also referred to as “a redistribution layer (RDL) structure”, “a substrate”, “an upper substrate”, “an upper wiring structure”, “an upper stacked structure”, “an upper conductive structure”, “a high-density circuit pattern structure”, “a high-density substrate”, “a high-density wiring structure”, “a high-density stacked structure”, “a high-density conductive structure”, “an upper circuit pattern structure”, “a second substrate”, “a second wiring structure”, “a second stacked structure”, or “a second conductive structure”.

The second circuit pattern structure 2 may be disposed on the first surface 31 (e.g., the top surface) of the first circuit pattern structure 3. The second circuit pattern structure 2 may include at least one dielectric layer (including, for example, a first dielectric layer 25 and a second dielectric layer 27) and at least one circuit layer (including, for example, a first circuit layer 24 and a second circuit layer 26) in contact with the dielectric layer (e.g., the dielectric layers 25, 27). In one embodiment, the second circuit pattern structure 2 may be similar to a coreless substrate, and may be in a wafer type, a panel type or a strip type. The second circuit pattern structure 2 may have a first surface 21 (e.g., a top surface), a second surface 22 (e.g., a bottom surface) opposite to the first surface 21 (e.g., the top surface), and a lateral surface 23 extending between the first surface 21 (e.g., the top surface) and the second surface 22 (e.g., the bottom surface).

The circuit layer (including, for example, the first circuit layer 24 and the second circuit layer 26) of the second circuit pattern structure 2 may be also referred to as “a high-density circuit layer”. In some embodiments, a density of a circuit line (including, for example, a trace or a pad) of the high-density circuit layer is greater than a density of a circuit line of a low-density circuit layer. That is, the count of the circuit line (including, for example, a trace or a pad) in a unit area of the high-density circuit layer is greater than the count of the circuit line in an equal unit area of the low-density circuit layer, such as about 1.2 times or greater, about 1.5 times or greater, or about 2 times or greater. Alternatively, or in combination, a line width/line space (L/S) of the high-density circuit layer is less than an L/S of the low-density circuit layer, such as about 90% or less, about 50% or less, or about 20% or less. Further, the conductive structure that includes the high-density circuit layer may be designated as the “high-density conductive structure”, and the conductive structure that includes the low-density circuit layer may be designated as a “low-density conductive structure”. That is, the line width/line space (L/S) of one of the plurality of circuit layers 24, 26 of the high-density conductive structure (e.g., the second circuit pattern structure 2) is less than an L/S of one of the plurality of circuit layers 34, 36, 38, 40 of the low-density conductive structure (e.g., the first circuit pattern structure 3).

The second circuit pattern structure 2 may include a plurality of dielectric layers (for example, the dielectric layers 25, 27), a plurality of circuit layers (for example, the circuit layers 24, 26) and a plurality of inner vias (for example, the first inner via 28 and the second inner via 29). The dielectric layers 25, 27 are stacked on one another. In one embodiment, a material of the first dielectric layer 25 and the second dielectric layer 27 may be a passivation layer, and may include, or be formed from, a photoresist layer, a cured photosensitive material, a cured photoimageable dielectric (PID) material such as a polyamide (PA), an Ajinomoto build-up film (ABF), a bismaleimide-triazine (BT), a polypropylene (PP), a polyimide (PI), epoxy or polybenzoxazole (PBO), or a combination of two or more thereof. In one embodiment, a second material of the dielectric layers 25, 27 of the second circuit pattern structure 2 includes a second resin material without fiber such as glass fiber. The first resin material of the first material of the dielectric layers 35, 37, 39 of the first circuit pattern structure 3 may be the same as or different from the second resin material of the second material of the dielectric layers 25, 27 of the second circuit pattern structure 2.

In addition, each of the circuit layers 24, 26 may include a plurality of traces and a plurality of pads. The circuit layers 24, 26, 34 are electrically connected to one another through the inner vias 28, 29. The first circuit layer 24 may be a fan-out circuit layer. A line width/line space (L/S) of the first circuit layer 24 may be less than or equal to 9 μm/12 μm, or less than or equal to 7 μm/10 μm, or less than or equal to 7 μm/9 μm, or less than or equal to 5 μm, 5 μm. In one embodiment, the first circuit layer 24 may be also referred to as “a signal transmission layer”, or “a first signal transmission layer” or “a topmost circuit layer”. In one embodiment, the first circuit layer 24 may include a seed layer 243 and a conductive metal material 244 (e.g., copper) disposed on the seed layer 243. The first dielectric layer 25 may cover the first circuit layer 24. Thus, the first circuit layer 24 may be embedded in the first dielectric layer 25. A top surface of the first circuit layer 24 may be substantially aligned with a top surface of the first dielectric layer 25.

The second circuit layer 26 may be a fan-out circuit layer, and a line width/line space (L/S) of the second circuit layer 26 may be less than or equal to 9 μm/12 μm, or less than or equal to 7 μm/10 μm, or less than or equal to 7 μm/9 μm, or less than or equal to 5 μm/5 μm. In one embodiment, the line width/line space (L/S) of the second circuit layer 26 may be equal to or greater than the line width/line space (L/S) of the first circuit layer 24. In one embodiment, the line width/line space (L/S) of the second circuit layer 26 of t he second circuit pattern structure 2 may be equal to or less than the line width/line space (L/S) of the first circuit layer 34 of the first circuit pattern structure 3. In one embodiment, the second circuit layer 26 may be a grounding layer. The second circuit layer 26 may be also referred to as “a second grounding layer”, or “a first grounding layer”. In one embodiment, the second circuit layer 26 may include a seed layer 263 and a conductive metal material 264 (e.g., copper) disposed on the seed layer 263. The second circuit layer 26 may be formed or disposed on the bottom surface of the first dielectric layer 25.

The first inner via 28 may be disposed in an opening of the first dielectric layer 25, and extend through the first dielectric layer 25 to contact and electrically connect the first circuit layer 24 and the second circuit layer 26. The first inner via 28 may include a seed layer 243 and a conductive metal material 244 (e.g., copper) disposed on the seed layer 243. In some embodiments, the second circuit layer 26 and the first inner via 28 may be formed integrally and concurrently. Thus, the seed layer 263 and the seed layer 283 may be the same layer. The conductive metal material 264 and the conductive metal material 284 may be the same layer. In addition, the first inner via 28 may taper upward. Thus, the first inner via 28 may taper toward the first electronic component 14 and the second electronic component 15. In one embodiment, the first inner via 41 may be also referred to as “a topmost inner via”.

The second dielectric layer 27 may cover the second circuit layer 26. Thus, the second circuit layer 26 may be embedded in the second dielectric layer 27. A top surface of the second circuit layer 26 may be substantially coplanar with a top surface of the second dielectric layer 27. The second dielectric layer 27 may be also referred to as “a bottommost dielectric layer of the second circuit pattern structure 2”.

The second inner via 29 may be disposed in an opening of the second dielectric layer 27, and extend through the second dielectric layer 27 to contact and electrically connect the second circuit layer 26 of the second circuit pattern structure 2 and the first circuit layer 34 of the first circuit pattern structure 3. The second inner via 29 may include a seed layer 293 and a conductive metal material 294 (e.g., copper) disposed on the seed layer 293. In some embodiments, the first circuit layer 34 of the first circuit pattern structure 3 and the second inner via 29 may be formed integrally and concurrently. Thus, the seed layer 343 and the seed layer 293 may be the same layer. The conductive metal material 344 and the conductive metal material 294 may be the same layer. In addition, the second inner via 29 may taper upward. Thus, the second inner via 29 may taper toward the first electronic component 14 and the second electronic component 15.

As shown in FIG. 1, a topmost one (e.g., the first dielectric layer 35) of the plurality of dielectric layers 35, 37, 39 of the first circuit pattern structure 3 (e.g., the low-density conductive structure) directly contacts a bottommost one (e.g., the second dielectric layer 27) of the plurality of dielectric layers 25, 27 of the second circuit pattern structure 2 (e.g., the high-density conductive structure). Thus, the second surface 22 (e.g., the bottom surface) of the second circuit pattern structure 2 directly contacts the first surface 31 (e.g., the top surface) of the first circuit pattern structure 3. In addition, a topmost one (e.g., the first circuit layer 34) of the plurality of circuit layers 34, 36, 38, 40 of the first circuit pattern structure 3 (e.g., the low-density conductive structure) directly contacts the bottommost one (e.g., the second dielectric layer 27) of the plurality of dielectric layers 25, 27 of the second circuit pattern structure 2 (e.g., the high-density conductive structure). Further, a width of one of the plurality of inner vias 41, 42, 43 of the first circuit pattern structure 3 (e.g., the low-density conductive structure) is greater than a width of one of the plurality of inner vias 28, 29 of the second circuit pattern structure 2 (e.g., the high-density conductive structure). All the inner vias 41, 42, 43 of the first circuit pattern structure 3 (e.g., the low-density conductive structure) and the inner vias 28, 29 of the second circuit pattern structure 2 (e.g., the high-density conductive structure) may taper toward the first electronic component 14 and the second electronic component 15.

As shown in FIG. 1, the package structure 1 may further include an upper protection layer 12 and a lower protection layer 13. The upper protection layer 12 may be disposed on the first surface 21 (e.g., the top surface) of the second circuit pattern structure 2, and may define a plurality of openings to expose portions of the first circuit layer 24 of the second circuit pattern structure 2. The lower protection layer 13 may be disposed on the second surface 32 (e.g., the bottom surface) of the first circuit pattern structure 3, and may define a plurality of openings to expose portions of the fourth circuit layer 40 of the first circuit pattern structure 3. A material of the upper protection layer 12 and the lower protection layer 13 may include a solder resist material.

The first electronic component 14 may be disposed over and electrically connected to the first surface 21 (e.g., the top surface) of the second circuit pattern structure 2 (e.g., the high-density conductive structure or the redistribution layer (RDL) structure). Thus, the first electronic component 14 may be disposed over and electrically connected to the first circuit layer 24 (e.g., the signal transmission layer) of the second circuit pattern structure 2. The first electronic component 14 may be an electronic device, a semiconductor element, a semiconductor chip or a semiconductor die such as a logic die, an application processor (AP) die, or an application specific integrated circuit (ASIC) die. The first electronic component 14 may a first surface (e.g., an active surface, a lower surface, or a bottom surface), a second surface (e.g., a back side surface, an upper surface, or a top surface) opposite to the first surface, and a lateral surface extending between the first surface and the second surface. The first surface of the first electronic component 14 may face the first surface 21 (e.g., the top surface) of the second circuit pattern structure 2.

The first electronic component 14 may include a plurality of bumps 144 extending beyond or protruding from the first surface. A material of the bumps 144 may be, for example, aluminum (Al), copper (Cu), tin (Sn), lead (Pb) or other suitable metals or alloy. In some embodiments, the bumps 144 of the first electronic component 14 may be bonded to the exposed portions (e.g., exposed pads) of the first circuit layer 24 of the second circuit pattern structure 2 through a plurality of bonding materials 145 such as solder material or reflowable material. A material of the bonding materials 145 may include silver-tin-alloy (AgSn).

The first underfill 16 may be formed or disposed between the first surface of the first electronic component 14 and the first surface 21 (e.g., the top surface) of the second circuit pattern structure 2 so as to cover and protect the joint formed by the bumps 144, the bonding materials 145 and the exposed portions (e.g., exposed pads) of the first circuit layer 24 of the second circuit pattern structure 2.

The second electronic component 15 may be disposed over and electrically connected to the first surface 21 (e.g., the top surface) of the second circuit pattern structure 2 (e.g., the high-density conductive structure or the redistribution layer (RDL) structure). Thus, the second electronic component 15 may be disposed over and electrically connected to the first circuit layer 24 (e.g., the signal transmission layer) of the second circuit pattern structure 2. The second electronic component 15 may be disposed side by side with the first electronic component 14. The second electronic component 15 may be spaced apart from the first electronic component 14.

The second electronic component 15 may be an electronic device, a semiconductor element, a semiconductor chip or a semiconductor die such as a memory die. The second electronic component 15 may a first surface (e.g., an active surface, a lower surface, or a bottom surface), a second surface (e.g., a back side surface, an upper surface, or a top surface) opposite to the first surface, and a lateral surface extending between the first surface and the second surface. The first surface of the second electronic component 15 may face the first surface 21 (e.g., the top surface) of the second circuit pattern structure 2.

In some embodiments, the second electronic component 15 may be bonded to the exposed portions (e.g., exposed pads) of the first circuit layer 24 of the second circuit pattern structure 2 through a plurality of bonding materials 155 such as solder material or reflowable material. A material of the bonding materials 155 may include silver-tin-alloy (AgSn).

The second underfill 17 may be formed or disposed between the first surface of the second electronic component 15 and the top surface of the upper protection layer 12 so as to cover and protect the bonding materials 155. In some embodiments, the second underfill 17 may be formed or disposed between the first surface of the second electronic component 15 and the first surface 21 (e.g., the top surface) of the second circuit pattern structure 2.

The encapsulant 18 may cover at least a portion of the first electronic component 14, at least a portion of the second electronic component 15, the first underfill 16, the second underfill 17 and the top surface of the upper protection layer 12. The encapsulant 18 may be disposed over the first surface 21 (e.g., the top surface) of the second circuit pattern structure 2. The encapsulant 18 may contact or may not contact be the first surface 21 (e.g., the top surface) of the second circuit pattern structure 2. A material of the encapsulant 18 may be a molding compound with or without fillers. In addition, the lateral surface of the encapsulant 18 may be substantially coplanar with the lateral surface 23 of the second circuit pattern structure 2 and the lateral surface 33 of the first circuit pattern structure 3.

The external connectors 19 may be disposed adjacent to the second surface 32 (e.g., the bottom surface) of the first circuit pattern structure 3 for external connection. The external connectors 19 may be solder materials or reflowable materials (e.g., solder balls). As shown in FIG. 1, the external connectors 19 are disposed on the exposed portions (i.e., the exposed via portions) of the fourth circuit layer 40 of the first circuit pattern structure 3.

As shown in the embodiment illustrated in FIG. 1, the first circuit pattern structure 3 and the second circuit pattern structure 2 may collectively define a wiring structure 10. Thus, the wiring structure 10 is a combination of the second circuit pattern structure 2 and the first circuit pattern structure 3, in which the circuit layers 24, 26 of the second circuit pattern structure 2 may have fine pitch, high yield and low thickness; and the circuit layers 34, 36, 38, 40 of the first circuit pattern structure 3 have low manufacturing cost. Thus, the wiring structure 10 has an advantageous compromise of yield and manufacturing cost, and the wiring structure 10 has a relatively low thickness.

The manufacturing yield for one layer of the circuit layers 24, 26 of the second circuit pattern structure 2 may be 99%, and the manufacturing yield for one layer of the circuit layers 34, 36, 38, 40 of the first circuit pattern structure 3 may be 90%. Thus, the yield of the wiring structure 10 may be improved. In addition, the dielectric layers 35, 37, 39 of the first circuit pattern structure 3 may include fibers so as to reduce the warpage of the wiring structure 10. Thus, the yield of the wiring structure 10 may be further improved. Therefore, the reliability and yield of the package structure 1 is improved. In addition, a number of input/output (I/O) count of the second circuit pattern structure 2 (e.g., the redistribution layer (RDL) structure) is less than a number of input/output (I/O) count of the first circuit pattern structure 3 (e.g., the substrate).

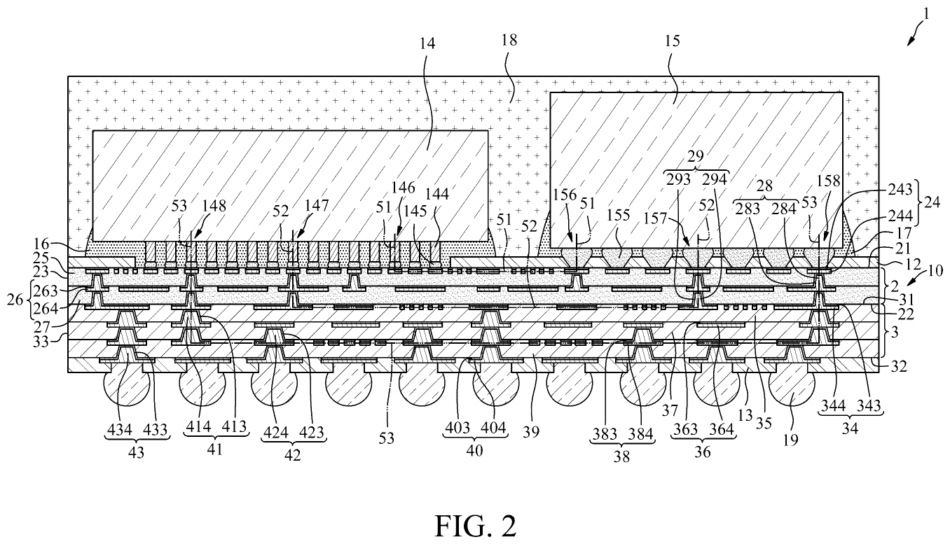

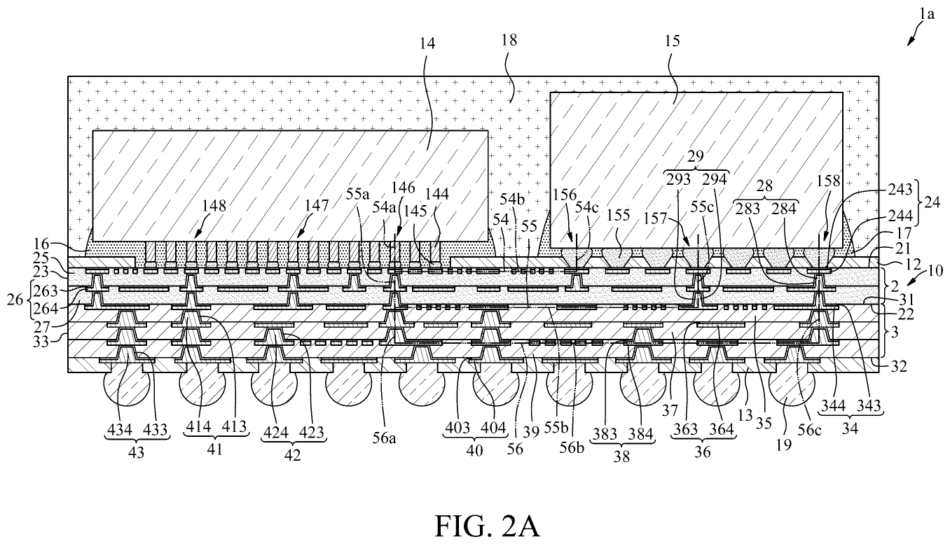

FIG. 2 illustrates a cross-sectional view of a plurality of signal transmission paths of the package structure 1 of FIG. 1. The first electronic component 14 may be electrically communicated with the second electronic component 15 through the first circuit layer 24 of the second circuit pattern structure 2, the first circuit layer 34 of the first circuit pattern structure 3 and the third circuit layer 38 of the first circuit pattern structure 3. The first circuit layer 24 of the second circuit pattern structure 2 may be also referred to as “first signal transmission layer”. The first circuit layer 34 of the first circuit pattern structure 3 may be also referred to as “second signal transmission layer”. The third circuit layer 38 of the first circuit pattern structure 3 may be also referred to as “third signal transmission layer” or “second circuit layer”. The first circuit layer 34 (e.g., the second signal transmission layer) of the first circuit pattern structure 3 may be disposed between the first circuit layer 24 (e.g., the first signal transmission layer) of the second circuit pattern structure 2 and the third circuit layer 38 (e.g., the third signal transmission layer or the second circuit layer) of the first circuit pattern structure 3.

In some embodiments, a signal transmission capacity of the first circuit layer 24 (e.g., the first signal transmission layer) of the second circuit pattern structure 2 may be greater than a signal transmission capacity of the first circuit layer 34 (e.g., the second signal transmission layer) of the first circuit pattern structure 3. The signal transmission capacity of the first circuit layer 34 (e.g., the second signal transmission layer) of the first circuit pattern structure 3 may be greater than a signal transmission capacity of the third circuit layer 38 (e.g., the third signal transmission layer or the second circuit layer) of the first circuit pattern structure 3.

The second circuit layer 26 of the second circuit pattern structure 2 may be a grounding layer, and may be also referred to as “a first grounding layer”. The second circuit layer 26 (e.g., the first grounding layer) of the second circuit pattern structure 2 may be disposed between the first circuit layer 24 (e.g., the first signal transmission layer) of the second circuit pattern structure 2 and the first circuit layer 34 (e.g., the second signal transmission layer) of the first circuit pattern structure 3. The second circuit layer 26 (e.g., the first grounding layer) of the second circuit pattern structure 2 can achieve a function of signal isolation, so as to reduce or suppress the cross-talk between the first circuit layer 24 (e.g., the first signal transmission layer) of the second circuit pattern structure 2 and the first circuit layer 34 (e.g., the second signal transmission layer) of the first circuit pattern structure 3.

The second circuit layer 36 of the first circuit pattern structure 3 may be a grounding layer, and may be also referred to as “a second grounding layer”. The second circuit layer 36 (e.g., the second grounding layer) of the first circuit pattern structure 3 may be disposed between the first circuit layer 34 (e.g., the second signal transmission layer) of the first circuit pattern structure 3 and the third circuit layer 38 (e.g., the third signal transmission layer or the second circuit layer) of the first circuit pattern structure 3. The second circuit layer 36 (e.g., the second grounding layer) of the first circuit pattern structure 3 can achieve a function of signal isolation, so as to reduce or suppress the cross-talk between the first circuit layer 34 (e.g., the second signal transmission layer) of the first circuit pattern structure 3 and the third circuit layer 38 (e.g., the third signal transmission layer or the second circuit layer) of the first circuit pattern structure 3.

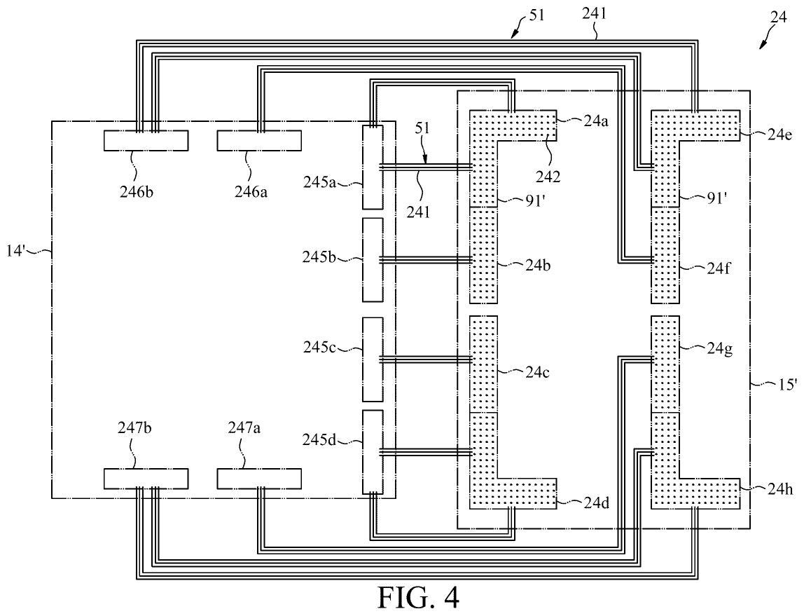

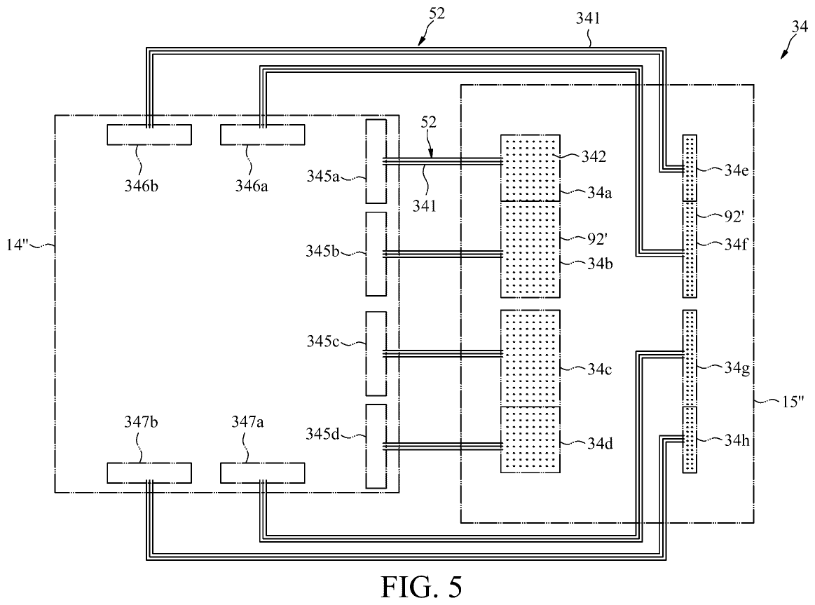

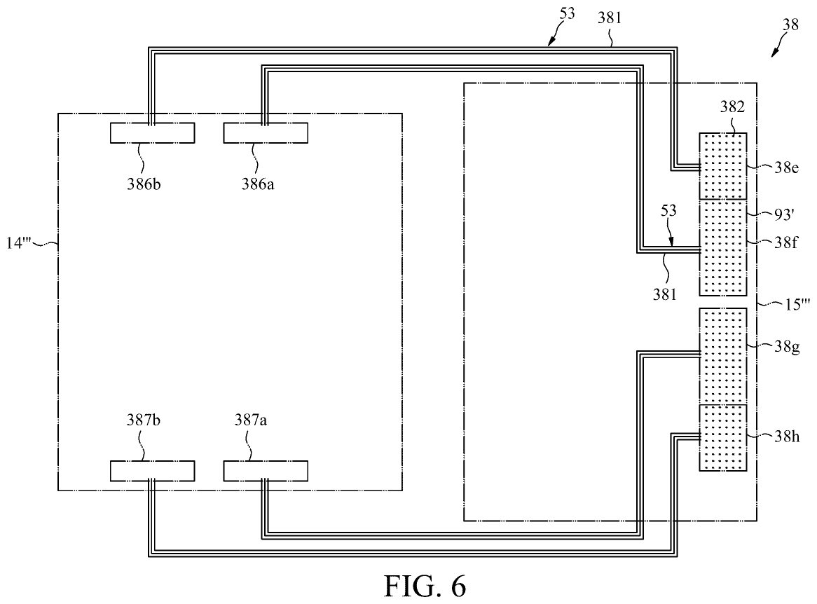

The package structure 1 may include a first signal transmission path 51, a second signal transmission path 52 and a third signal transmission path 53 configured to transmit signals from the first electronic component 14 to the second electronic component 15 or from the second electronic component 15 to the first electronic component 14. Thus, the first electronic component 14 may be electrically communicated with the second electronic component 15 through the first signal transmission path 51, the second signal transmission path 52 and the third signal transmission path 53. The first signal transmission path 51 may pass through the trace 241 (FIG. 4) of the first circuit layer 24 of the second circuit pattern structure 2. The second signal transmission path 52 may pass through the trace 341 (FIG. 5) of the first circuit layer 34 of the first circuit pattern structure 3. The third signal transmission path 53 may pass through the trace 381 (FIG. 6) of and the third circuit layer 38 of the first circuit pattern structure 3.

The first electronic component 14 may include a first region 146, a second region 147 and a third region 148. Each of the first region 146, the second region 147 and the third region 148 may be a signal transmission region. The first region 146 is closest to the second electronic component 15. The second region 147 is closer to the second electronic component 15 than the third region 148 is. The second region 147 is disposed between the first region 146 and the third region 148. Similarly, the second electronic component 15 may include a first region 156, a second region 157 and a third region 158. Each of the first region 156, the second region 157 and the third region 158 may be a signal transmission region. The first region 156 is closest to the first electronic component 14. The second region 157 is closer to the first electronic component 14 than the third region 158 is. The second region 157 is disposed between the first region 156 and the third region 158.

The first signal transmission path 51 may extend from the first region 156 of the second electronic component 15 to the first region 146 of the first electronic component 14 through the trace 241 (FIG. 4) of the first circuit layer 24 of the second circuit pattern structure 2. Thus, the first region 156 of the second electronic component 15 may be electrically communicated with the first region 146 of the first electronic component 14 through the trace 241 (FIG. 4) of the first circuit layer 24 of the second circuit pattern structure 2 along the first signal transmission path 51.

The second signal transmission path 52 may extend from the second region 157 of the second electronic component 15 to the second region 147 of the first electronic component 14 through the trace 341 (FIG. 5) of the first circuit layer 34 of the first circuit pattern structure 3. Thus, the second region 157 of the second electronic component 15 may be electrically communicated with the second region 147 of the first electronic component 14 through the trace 341 (FIG. 5) of the first circuit layer 34 of the first circuit pattern structure 3 along the second signal transmission path 52.

The third signal transmission path 53 may extend from the third region 158 of the second electronic component 15 to the third region 148 of the first electronic component 14 through the trace 381 (FIG. 6) of and the third circuit layer 38 of the first circuit pattern structure 3. Thus, the third region 158 of the second electronic component 15 may be electrically communicated with the third region 148 of the first electronic component 14 through the trace 381 (FIG. 6) of and the third circuit layer 38 of the first circuit pattern structure 3 along the third signal transmission path 53. As shown in FIG. 2, a total length of the first signal transmission path 51 may be shorter than a total length of the second signal transmission path 52. The total length of the second signal transmission path 52 may be shorter than a total length of the third signal transmission path 53.

FIG. 2A illustrates a cross-sectional view of a plurality of signal transmission paths of a package structure 1a according to some embodiments of the present disclosure. The package structure 1a of FIG. 2A is similar to the package structure 1 of FIG. 2. The first region 146 of the first electronic component 14 may be electrically connected to or electrically communicated with the first region 156, the second region 157 and the third region 158 of the second electronic component 15 concurrently. An area of the first region 146 of the first electronic component 14 is less than an area of the first region 156, an area of the second region 157 and an area of the third region 158 of the second electronic component 15. The first region 156, the second region 157 and the third region 158 of the second electronic component 15 do not overlap each other in a direction perpendicular to the first surface 21 (e.g., the top surface) of the second circuit pattern structure 2 (e.g., a redistribution layer (RDL) structure).

In addition, the first region 146 of the first electronic component 14 is electrically connected to the first region 156 by a first signal transmission path 54. The first signal transmission path 54 passes through the signal transmission layer 24. The first region 146 of the first electronic component 14 is electrically connected to the second region 157 by a second signal transmission path 55. The second signal transmission path 55 passes through the first circuit layer 34. The first region 146 of the first electronic component 14 is electrically connected to the third region 158 by a third signal transmission path 56. The third signal transmission path 56 passes through the second circuit layer 38. An entire length of the first signal transmission path 54 is shorter than an entire length of the second signal transmission path 55. The entire length of the second signal transmission path 55 is shorter than an entire length of the third signal transmission path 56. Further, a signal transmission capacity of the second signal transmission path 55 is less than a signal transmission capacity of the first signal transmission path 54. A signal transmission capacity of the third signal transmission path 56 is less than the signal transmission capacity of the second signal transmission path 55.

The first signal transmission path 54, the second signal transmission path 55 and the third signal transmission path 56 may overlap each other in the direction perpendicular to the first surface 21 (e.g., the top surface) of the second circuit pattern structure 2 (e.g., a redistribution layer (RDL) structure). The first signal transmission path 54 may have a first vertical portion 54a, a second vertical portion 54c and a horizontal portion 54b connecting the first vertical portion 54a and the second vertical portion 54c. The horizontal portion 54b may be disposed in the signal transmission layer 24. The first vertical portion 54a may be disposed between the first electronic component 14 and the signal transmission layer 24 (e.g., the horizontal portion 54b). The second vertical portion 54c may be disposed between the second electronic component 15 and the signal transmission layer 24 (e.g., the horizontal portion 54b). In addition, the second signal transmission path 55 may have a first vertical portion 55a, a second vertical portion 55c and a horizontal portion 55b connecting the first vertical portion 55a and the second vertical portion 55c. The horizontal portion 55b may be disposed in the first circuit layer 34. The first vertical portion 55a may be disposed between the first electronic component 14 and the first circuit layer 34 (e.g., the horizontal portion 55b). The second vertical portion 55c may be disposed between the second electronic component 15 and the first circuit layer 34 (e.g., the horizontal portion 55b). In addition, the third signal transmission path 56 may have a first vertical portion 56a, a second vertical portion 56c and a horizontal portion 56b connecting the first vertical portion 56a and the second vertical portion 56c. The horizontal portion 56b may be disposed in the second circuit layer 38. The first vertical portion 56a may be disposed between the first electronic component 14 and the second circuit layer 38 (e.g., the horizontal portion 56b). The second vertical portion 56c may be disposed between the second electronic component 15 and the second circuit layer 38 (e.g., the horizontal portion 56b). Further, the horizontal portion 55b of the second signal transmission path 55 is longer than the horizontal portion 54b of the first signal transmission path 54. The horizontal portion 56b of the third signal transmission path 56 is longer than the horizontal portion 55b of the second signal transmission path 55. The vertical portions 55a, 55c of the second signal transmission path 55 is longer than the vertical portions 54a, 54c of the first signal transmission path 54. The vertical portions 56a, 56c of the third signal transmission path 56 is longer than the vertical portions 55a, 55c of the second signal transmission path.

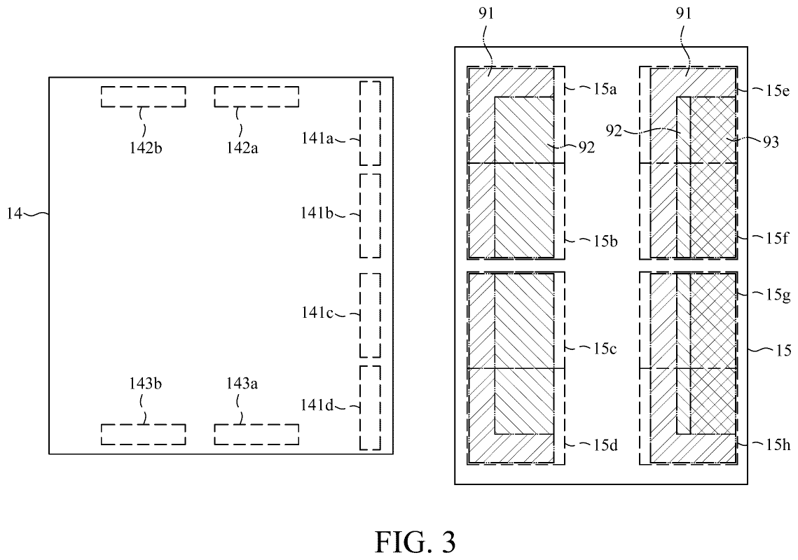

FIG. 3 illustrates a top view of the first electronic component 14 and the second electronic component 15 of the package structure 1 of FIG. 1. The first electronic component 14 may include a first channel 141a, a second channel 141b, a third channel 141c, a fourth channel 141d, a fifth channel 142a, a sixth channel 142b, a seventh channel 143a and an eighth channel 143b. The signals (e.g., electrical signals) may enter or exit from the first electronic component 14 through the eight channels 141a, 141b, 141c, 141d, 142a, 142b, 143a, 143b of the first electronic component 14. The signals (e.g., electrical signals) may be transmitted into or out from the first electronic component 14 through the eight channels 141a, 141b, 141c, 141d, 142a, 142b, 143a, 143b of the first electronic component 14. Each of the eight channels 141a, 141b, 141c, 141d, 142a, 142b, 143a, 143b of the first electronic component 14 may be an input/output channel.

In some embodiments, the first channel 141a, the second channel 141b, the third channel 141c and the fourth channel 141d may correspond to the first region 146 and the second region 147 of FIG. 2. The fifth channel 142a, the sixth channel 142b, the seventh channel 143a and the eighth channel 143b may correspond to the third region 148 of FIG. 2. In some embodiments, the first channel 141a, the second channel 141b, the third channel 141c and the fourth channel 141d may correspond to the first region 146 of FIG. 2. The fifth channel 142a and the seventh channel 143a may correspond to the second region 147 of FIG. 2. The sixth channel 142b and the eighth channel 143b may correspond to the third region 148 of FIG. 2.

The second electronic component 15 may include a first channel 15a, a second channel 15b, a third channel 15c, a fourth channel 15d, a fifth channel 15e, a sixth channel 15f, a seventh channel 15g and an eighth channel 15h. The signals (e.g., electrical signals) may enter or exit from the second electronic component 15 through the eight channels 15a, 15b, 15c, 15d, 15e, 15f, 15g, 15h of the second electronic component 15. The signals (e.g., electrical signals) may be transmitted into or out from the second electronic component 15 through the eight channels 15a, 15b, 15c, 15d, 15e, 15f, 15g, 15h of the second electronic component 15. Each of the eight channels 15a, 15b, 15c, 15d, 15e, 15f, 15g, 15h of the second electronic component 15 may be an input/output channel.

In some embodiments, the total area of the eight channels 15a, 15b, 15c, 15d, 15e, 15f, 15g, 15h of the second electronic component 15 may be divided into three regions. For example, the second electronic component 15 may include a first region 91, a second region 92 and a third region 93. The first region 91 may cover a first portion of the first channel 15a, a first portion of the second channel 15b, a first portion of the third channel 15c, a first portion of the fourth channel 15d, a first portion of the fifth channel 15e, a first portion of the sixth channel 15f, a first portion of the seventh channel 15g and a first portion of the eighth channel 15h. The second region 92 may cover a second portion of the first channel 15a, a second portion of the second channel 15b, a second portion of the third channel 15c, a second portion of the fourth channel 15d, a second portion of the fifth channel 15e, a second portion of the sixth channel 15f, a second portion of the seventh channel 15g and a second portion of the eighth channel 15h. The third region 93 may cover a third portion of the fifth channel 15e, a third portion of the sixth channel 15f, a third portion of the seventh channel 15g and a third portion of the eighth channel 15h.

Each of the first region 91, the second region 92 and the third region 93 may be a signal transmission region. The first region 91 may be closest to the first electronic component 14. The second region 92 may be closer to the first electronic component 14 than the third region 93 is. The second region 92 may be disposed between the first region 91 and the third region 93. The first region 91 of FIG. 3 may correspond to the first region 156 of FIG. 2. The second region 92 of FIG. 3 may correspond to the second region 157 of FIG. 2. The third region 93 of FIG. 3 may correspond to the third region 158 of FIG. 2.

FIG. 4 illustrates a layout of the first circuit layer 24 of the second circuit pattern structure 2 of the package structure 1 of FIG. 1. The first circuit layer 24 of the second circuit pattern structure 2 may include a plurality of traces 241 and a plurality of pads 242. The traces 241 may be a portion of the first signal transmission path 51. Each of the pads 242 may be an input/output (I/O) connection for signal transmission. The first circuit layer 24 may include a first number of pads 242 or a first number of input/output (I/O) count. Each of the pads 242 may be connected to a trace 241. To ensure clarity in the drawing, the number of the traces 241 and pads 242 has been simplified.

The layout of the first circuit layer 24 may include a first area 14′, a second area 15′, a first subarea 245a, a second subarea 245b, a third subarea 245c, a fourth subarea 245d, a fifth subarea 246a, a sixth subarea 246b, a seventh subarea 247a, an eighth subarea 247b and a first region 91′. The first area 14′ may correspond to the first electronic component 14, and the second area 15′ may correspond to the second electronic component 15. The first subarea 245a, the second subarea 245b, the third subarea 245c, the fourth subarea 245d, the fifth subarea 246a, the sixth subarea 246b, the seventh subarea 247a and the eighth subarea 247b in the first area 14′ of FIG. 4 may correspond to the first channel 141a, the second channel 141b, the third channel 141c, the fourth channel 141d, the fifth channel 142a, the sixth channel 142b, the seventh channel 143a and the eighth channel 143b of FIG. 3, respectively.

The first region 91′ in the second area 15′ of FIG. 4 may correspond to the first region 91 of FIG. 3. The first region 91′ of FIG. 4 may include a first subregion 24a, a second subregion 24b, a third subregion 24c, a fourth subregion 24d, a fifth subregion 24e, a sixth subregion 24f, a seventh subregion 24g and an eighth subregion 24h. The pads 242 may be disposed in the first region 91′. The traces 241 may extend from the first subregion 24a to the first subarea 245a, from the second subregion 24b to the second subarea 245b, from the third subregion 24c to the third subarea 245c, from the fourth subregion 24d to the fourth subarea 245d, from the fifth subregion 24e to the sixth subarea 246b, from the sixth subregion 24f to the fifth subarea 246a, from the seventh subregion 24g to the seventh subarea 247a, and from the eighth subregion 24h to the eighth subarea 247b.

FIG. 5 illustrates a layout of the first circuit layer 34 of the first circuit pattern structure 3 of the package structure 1 of FIG. 1. The first circuit layer 34 of the first circuit pattern structure 3 may include a plurality of traces 341 and a plurality of pads 342. The traces 341 may be a portion of the second signal transmission path 52. Each of the pads 342 may be an input/output (I/O) for signal transmission. The first circuit layer 34 may include a second number of pads 342 or a second number of input/output (I/O) count. Each of the pads 342 may be connected to a trace 341. To ensure clarity in the drawing, the number of the traces 341 and pads 342 has been simplified.

The layout of the first circuit layer 34 may include a first area 14″, a second area 15″, a first subarea 345a, a second subarea 345b, a third subarea 345c, a fourth subarea 345d, a fifth subarea 346a, a sixth subarea 346b, a seventh subarea 347a, an eighth subarea 347b and a second region 92′. The first area 14″ may correspond to the first electronic component 14, and the second area 15″ may correspond to the second electronic component 15. The first subarea 345a, the second subarea 345b, the third subarea 345c, the fourth subarea 345d, the fifth subarea 346a, the sixth subarea 346b, the seventh subarea 347a and the eighth subarea 347b in the first area 14″ of FIG. 5 may correspond to the first channel 141a, the second channel 141b, the third channel 141c, the fourth channel 141d, the fifth channel 142a, the sixth channel 142b, the seventh channel 143a and the eighth channel 143b of FIG. 3, respectively.

The second region 92′ in the second area 15″ of FIG. 5 may correspond to the second region 92 of FIG. 3. The second region 92′ of FIG. 5 may include a first subregion 34a, a second subregion 34b, a third subregion 34c, a fourth subregion 34d, a fifth subregion 34e, a sixth subregion 34f, a seventh subregion 34g and an eighth subregion 34h. The pads 342 may be disposed in the second region 92′. The traces 341 may extend from the first subregion 34a to the first subarea 345a, from the second subregion 34b to the second subarea 345b, from the third subregion 34c to the third subarea 345c, from the fourth subregion 34d to the fourth subarea 345d, from the fifth subregion 34e to the sixth subarea 346b, from the sixth subregion 34f to the fifth subarea 346a, from the seventh subregion 34g to the seventh subarea 347a, and from the eighth subregion 34h to the eighth subarea 347b.

As shown in FIG. 4 and FIG. 5, a distance between the first region 91′ in the second area 15′ and the first area 14′ of FIG. 4 may be less than a distance between the second region 92′ in the second area 15″ and the first area 14″ of FIG. 5. Thus, the trace 241 (e.g., the first signal transmission path 51) of the first circuit layer 24 of FIG. 4 may be shorter the trace 341 (e.g., the second signal transmission path 52) of the first circuit layer 34 of FIG. 5. In addition, the first number of pads 242 may be greater than the second number of pads 342. In one embodiment, the first number may be 544, and the second number may be 440. Thus, the signal transmission capacity of the first circuit layer 24 (e.g., the first signal transmission layer) of the second circuit pattern structure 2 may be greater than the signal transmission capacity of the first circuit layer 34 (e.g., the second signal transmission layer) of the first circuit pattern structure 3.

FIG. 6 illustrates a layout of the third circuit layer 38 of the first circuit pattern structure 3 of the package structure 1 of FIG. 1. The third circuit layer 38 of the first circuit pattern structure 3 may include a plurality of traces 381 and a plurality of pads 382. The traces 381 may be a portion of the third signal transmission path 53. Each of the pads 382 may be an input/output (I/O) for signal transmission. The third circuit layer 38 may include a third number of pads 382 or a third number of input/output (I/O) count. Each of the pads 382 may be connected to a trace 381. To ensure clarity in the drawing, the number of the traces 381 and pads 382 has been simplified.

In some embodiments, the first number of input/output (I/O) count of the signal transmission layer 24 may be greater than the second number of input/output (I/O) count of the first circuit layer 34. The second number of input/output (I/O) count of the first circuit layer 34 may be greater than the third number of input/output (I/O) count of the second circuit layer 38. In addition, a sum of the second number of input/output (I/O) count of the first circuit layer 34 and the third number of input/output (I/O) count of the second circuit layer 38 may be greater than the first number of input/output (I/O) count of the signal transmission layer 24.

The layout of the third circuit layer 38 may include a first area 14″″, a second area 15″″, a fifth subarea 386a, a sixth subarea 386b, a seventh subarea 387a, an eighth subarea 387b and a third region 93′. The first area 14″″ may correspond to the first electronic component 14, and the second area 15″″ may correspond to the second electronic component 15. The fifth subarea 386a, the sixth subarea 386b, the seventh subarea 387a and the eighth subarea 387b in the first area 14″″ of FIG. 6 may correspond to the fifth channel 142a, the sixth channel 142b, the seventh channel 143a and the eighth channel 143b of FIG. 3, respectively.

The third region 93′ in the second area 15″″ of FIG. 6 may correspond to the third region 93 of FIG. 3. The third region 93′ of FIG. 6 may include a fifth subregion 38e, a sixth subregion 38f, a seventh subregion 38g and an eighth subregion 38h. The pads 382 may be disposed in the third region 93′. The traces 381 may extend from the from the fifth subregion 38e to the sixth subarea 386b, from the sixth subregion 38f to the fifth subarea 386a, from the seventh subregion 38g to the seventh subarea 387a, and from the eighth subregion 38h to the eighth subarea 387b.

As shown in FIG. 5 and FIG. 6, the distance between the second region 92′ in the second area 15″ and the first area 14″ of FIG. 5 may be less than a distance between the third region 93′ in the second area 15″″ and the first area 14″″ of FIG. 6. Thus, the trace 341 (e.g., the second signal transmission path 52) of the first circuit layer 34 of FIG. 5 may be shorter the trace 381 (e.g., the third signal transmission path 53) of the third circuit layer 38 of FIG. 6. In addition, the second number of pads 342 may be greater than the third number of pads 382. In one embodiment, the third number may be 264. Thus, the signal transmission capacity of the first circuit layer 34 (e.g., the second signal transmission layer) of the first circuit pattern structure 3 may be greater than the signal transmission capacity of the third circuit layer 38 (e.g., the third signal transmission layer or the second circuit layer) of the first circuit pattern structure 3. The signal transmission capacity of the first circuit layer 24 (e.g., the first signal transmission layer) of the second circuit pattern structure 2 may be greater than the signal transmission capacity of the third circuit layer 38 (e.g., the third signal transmission layer or the second circuit layer) of the first circuit pattern structure 3.

In one embodiment, a total number of the pads 242, 342, 382 may be 1248. Thus, a first ratio of the first number to the total number may be 43.6%, a second ratio of the second number to the total number may be 35.3%, and a third ratio of the third number to the total number may be 21.1%. A total signal transmission capacity may be defined as a sum of the signal transmission capacity of the first circuit layer 24 (e.g., the first signal transmission layer) of the second circuit pattern structure 2, the signal transmission capacity of the first circuit layer 34 (e.g., the second signal transmission layer) of the first circuit pattern structure 3 and the signal transmission capacity of the third circuit layer 38 (e.g., the third signal transmission layer or the second circuit layer) of the first circuit pattern structure 3. A first ratio of the signal transmission capacity of the first circuit layer 24 (e.g., the first signal transmission layer) of the second circuit pattern structure 2 to the total signal transmission capacity may be about 40% to 50%, or about 40% to 45%. A second ratio of the signal transmission capacity of the first circuit layer 34 (e.g., the second signal transmission layer) of the first circuit pattern structure 3 to the total signal transmission capacity may be about 30% to 40%, or about 33% to 37%. A third ratio of the signal transmission capacity of the third circuit layer 38 (e.g., the third signal transmission layer or the second circuit layer) of the first circuit pattern structure 3 to the total signal transmission capacity may be about 20% to 30%, or about 20% to 25%.

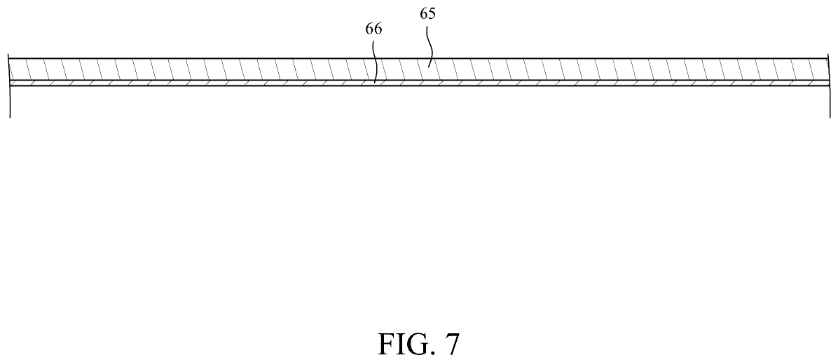

FIG. 7 through FIG. 24 illustrate a method for manufacturing a package structure 1 according to some embodiments of the present disclosure.

Referring to FIG. 7, a carrier 65 is provided. The carrier 65 may be a glass carrier, and may be in a wafer type, a panel type or a strip type. Then, a release layer 66 is coated on a bottom surface of the carrier 65.

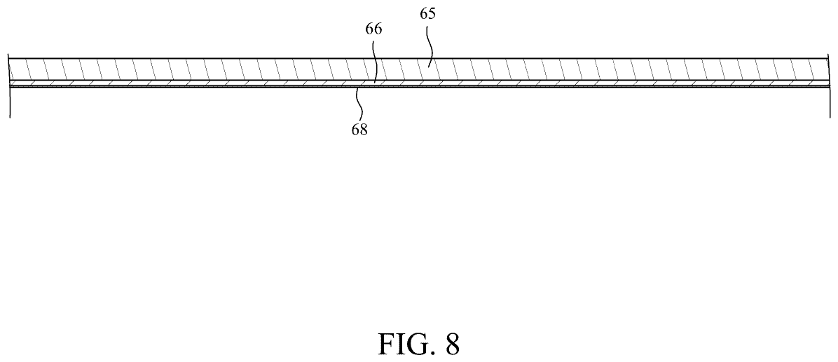

Referring to FIG. 8, a seed layer 68 is formed or disposed on the release layer 66 by a physical vapor deposition (PVD) technique or other suitable techniques.

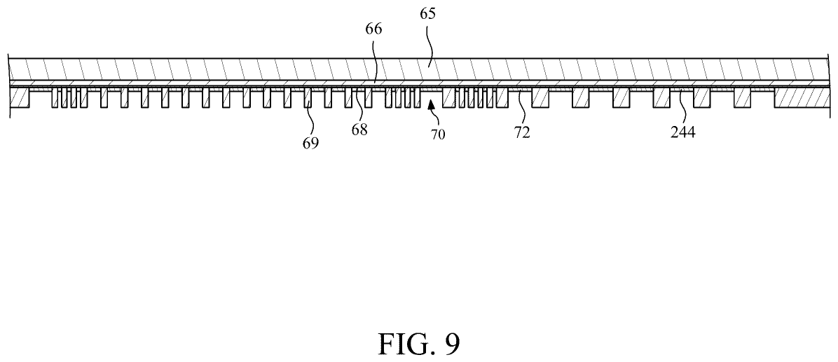

Referring to FIG. 9, a photoresist layer 69 is formed on the seed layer 68. Then, the photoresist layer 69 is patterned to form at least one opening 70 to extend through the photoresist layer 69 to expose portions of the seed layer 68 by an exposure and development technique or other suitable techniques. Then, a conductive material 72 (e.g., a metallic material) is disposed in the openings 70 of the photoresist layer 69 and on the seed layer 68 by a plating technique or other suitable techniques, so as to form the conductive metal material 244.

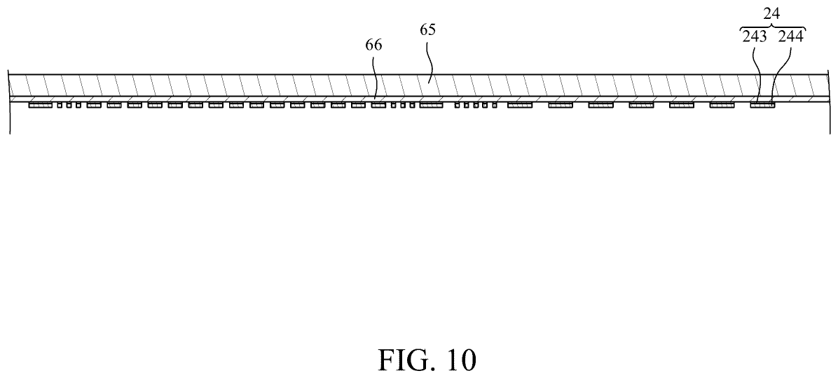

Referring to FIG. 10, the photoresist layer 69 is removed by a stripping technique or other suitable techniques. Then, portions of the seed layer 68 that are not covered by the conductive metal material 244 are removed by an etching technique or other suitable techniques. Meanwhile, a first circuit layer 24 is formed. The first circuit layer 24 may include a seed layer 243 formed from the seed layer 68 and a conductive metal material 244 disposed on the seed layer 243.

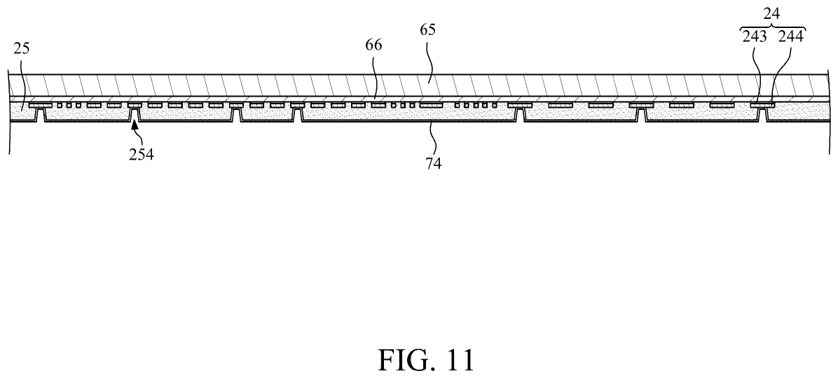

Referring to FIG. 11, a first dielectric layer 25 is formed on the release layer to cover the first circuit layer 24 by a coating technique or other suitable techniques. Then, at least one through hole 254 is formed to extend through the first dielectric layer 25 to expose a portion of the first circuit layer 24 by an exposure and development technique or other suitable techniques. Then, a seed layer 74 is formed on a bottom surface of the first dielectric layer 25 and in the through hole 254 by a PVD technique or other suitable techniques.

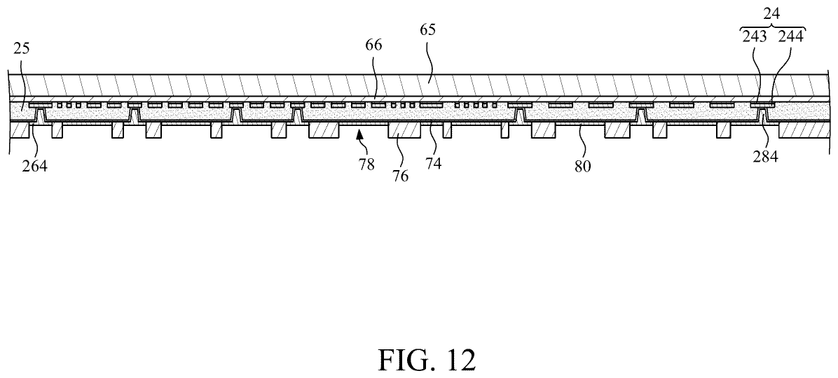

Referring to FIG. 12, a photoresist layer 76 is formed on the seed layer 74. Then, the photoresist layer 76 is patterned to expose portions of the seed layer 74 by an exposure and development technique or other suitable techniques. The photoresist layer 76 defines a plurality of openings 78. At least one opening 78 of the photoresist layer 76 corresponds to, and is aligned with, the through hole 254 of the first dielectric layer 25. Then, a conductive material 80 (e.g., a metallic material) is disposed in the openings 78 of the photoresist layer 76 and on the seed layer 74 by a plating technique or other suitable techniques.

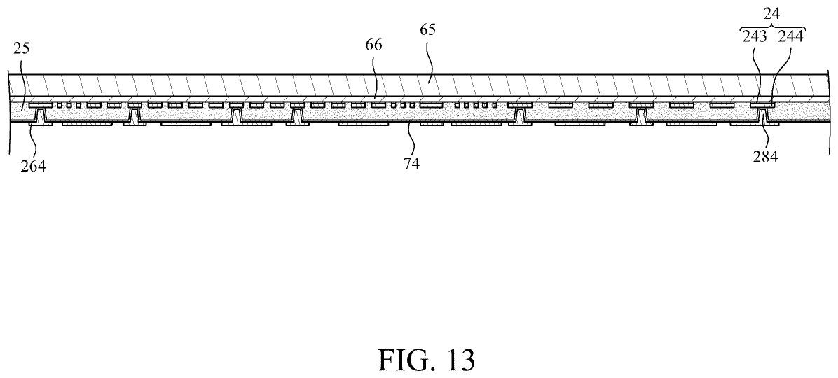

Referring to FIG. 13, the photoresist layer 76 is removed by a stripping technique or other suitable techniques.

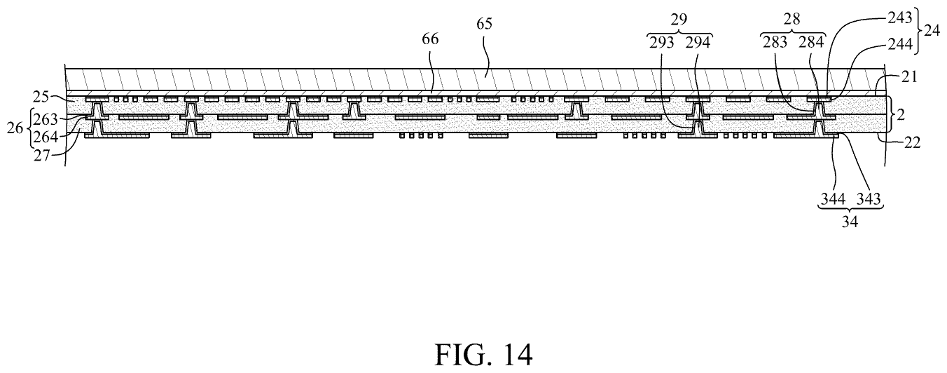

Referring to FIG. 14, portions of the seed layer 74 that are not covered by the conductive material 80 are removed by an etching technique or other suitable techniques. Meanwhile, a second circuit layer 26 and at least one first inner via 28 are formed. The second circuit layer 26 may be formed or disposed on the bottom surface of the first dielectric layer 25. In some embodiments, the second circuit layer 26 may include a seed layer 263 formed from the seed layer 74 and a conductive metal material 264 disposed on the seed layer 263 and formed from the conductive material 80. The first inner via 28 may be disposed in the through hole 254 of the first dielectric layer 25. The first inner via 28 may include a seed layer 283 formed from the seed layer 74 and a conductive metal material 284 disposed on the seed layer 283 and formed from the conductive material 80. In addition, the first inner via 28 may taper upward.

Then, a second dielectric layer 27, a first circuit layer 34 and at least one second inner via 29 are formed by repeating the abovementioned stages. Meanwhile, a second circuit pattern structure 2 is formed. The second circuit pattern structure 2 may be a RDL structure and may be formed on the carrier 65 through laminating.

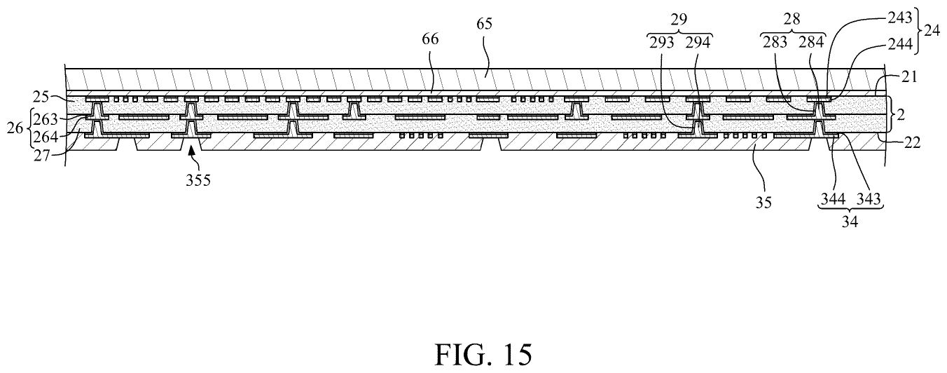

Referring to FIG. 15, a first dielectric layer 35 is formed on the second dielectric layer 27 of the second circuit pattern structure 2 to cover the first circuit layer 34 by a coating technique or other suitable techniques. Then, at least one through hole 355 is formed to extend through the first dielectric layer 35 to expose a portion of the first circuit layer 34 by an exposure and development technique or other suitable techniques.

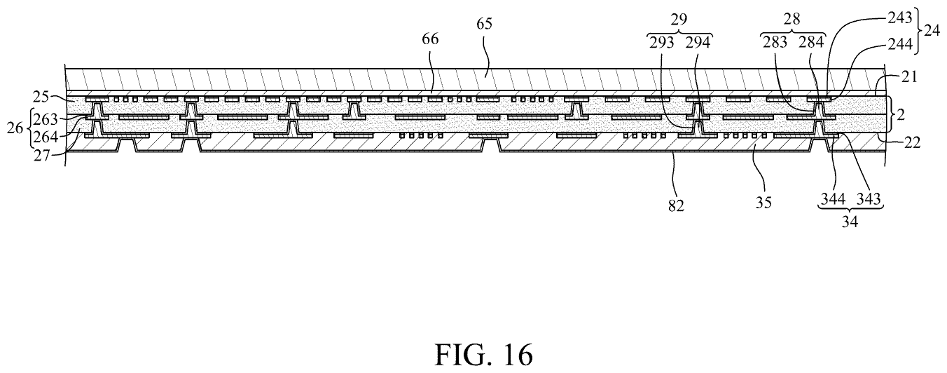

Referring to FIG. 16, a seed layer 82 is formed on a bottom surface of the first dielectric layer 35 and in the through hole 355 by a PVD technique or other suitable techniques.

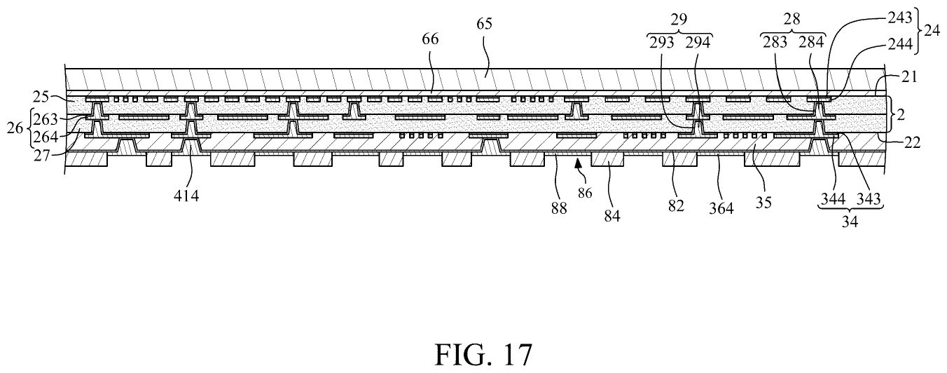

Referring to FIG. 17, a photoresist layer 84 is formed on the seed layer 82. Then, the photoresist layer 84 is patterned to expose portions of the seed layer 82 by an exposure and development technique or other suitable techniques. The photoresist layer 84 defines a plurality of openings 86. At least one opening 86 of the photoresist layer 84 corresponds to, and is aligned with, the through hole 355 of the first dielectric layer 35. Then, a conductive material 88 (e.g., a metallic material) is disposed in the openings 86 of the photoresist layer 84 and on the seed layer 82 by a plating technique or other suitable techniques.

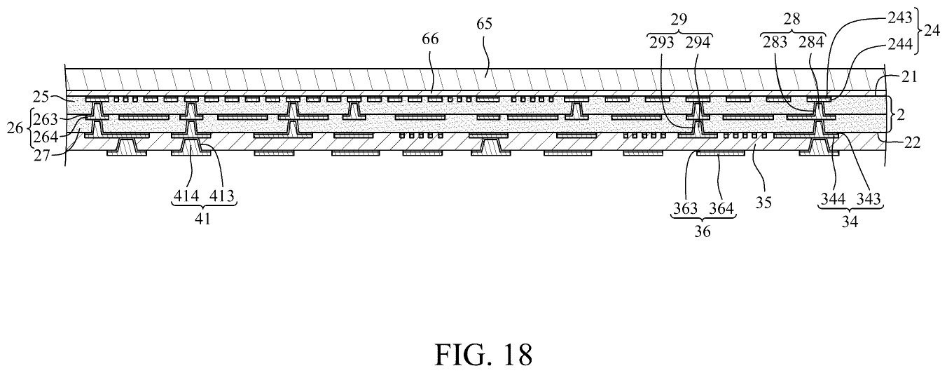

Referring to FIG. 18, the photoresist layer 84 is removed by a stripping technique or other suitable techniques. Then, portions of the seed layer 82 that are not covered by the conductive material 88 are removed by an etching technique or other suitable techniques. Meanwhile, a second circuit layer 36 and at least one first inner via 41 are formed. The second circuit layer 36 may be formed or disposed on the bottom surface of the first dielectric layer 35. In some embodiments, the second circuit layer 36 may include a seed layer 363 formed from the seed layer 82 and a conductive metal material 364 disposed on the seed layer 363 and formed from the conductive material 88. The first inner via 41 may b e disposed in the through hole 355 of the first dielectric layer 35. The first inner via 41 may include a seed layer 413 formed from the seed layer 82 and a conductive metal material 414 disposed on the seed layer 413 and formed from the conductive material 88. In addition, the first inner via 41 may taper upward.

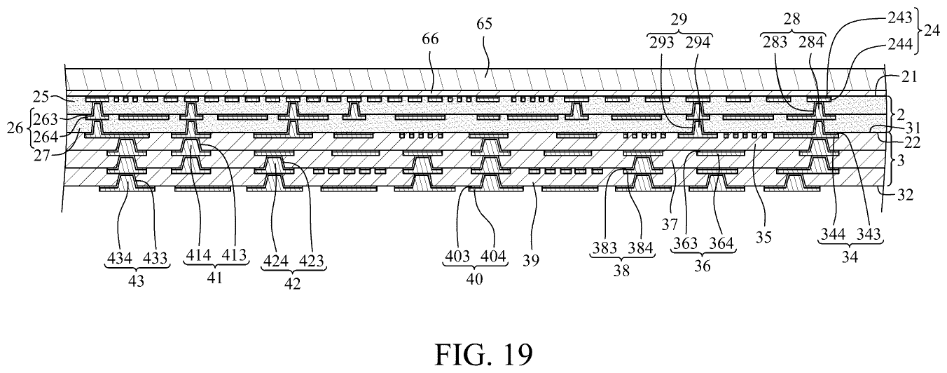

Referring to FIG. 19, a second dielectric layer 37, a third circuit layer 38, at least one second inner via 42, a third dielectric layer 39, a fourth circuit layer 40 and at least one third inner via 43 are formed by repeating the abovementioned stages. Meanwhile, a first circuit pattern structure 3 is formed. The first circuit pattern structure 3 may be a substrate and may be formed on the second circuit pattern structure 2 (e.g., the RDL structure) through laminating before the carrier 65 and the release layer 66 are removed.

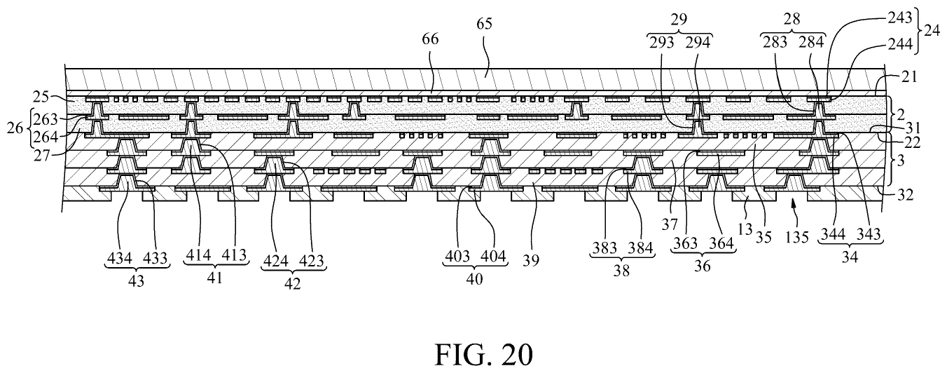

Referring to FIG. 20, a lower protection layer 13 is formed or disposed on the second surface 32 (e.g., the bottom surface) of the first circuit pattern structure 3. The lower protection layer 13 may define a plurality of openings 135 to expose portions of the fourth circuit layer 40 of the first circuit pattern structure 3.

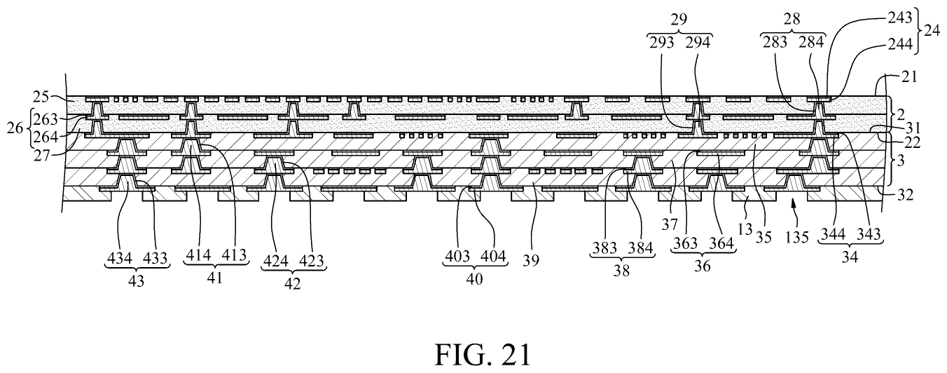

Referring to FIG. 21, the carrier 65 and the release layer 66 are removed.

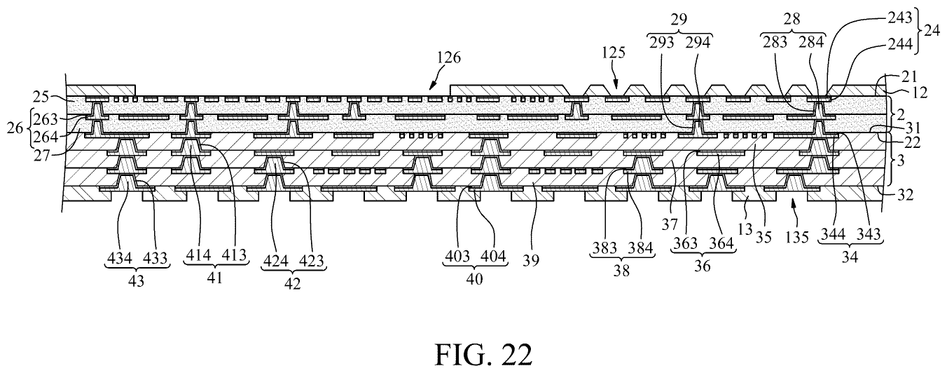

Referring to FIG. 22, an upper protection layer 12 may be formed or disposed on the first surface 21 (e.g., the top surface) of the second circuit pattern structure 2. The upper protection layer 12 may define a plurality of openings 125, 126 to expose portions of the first circuit layer 24 of the second circuit pattern structure 2.

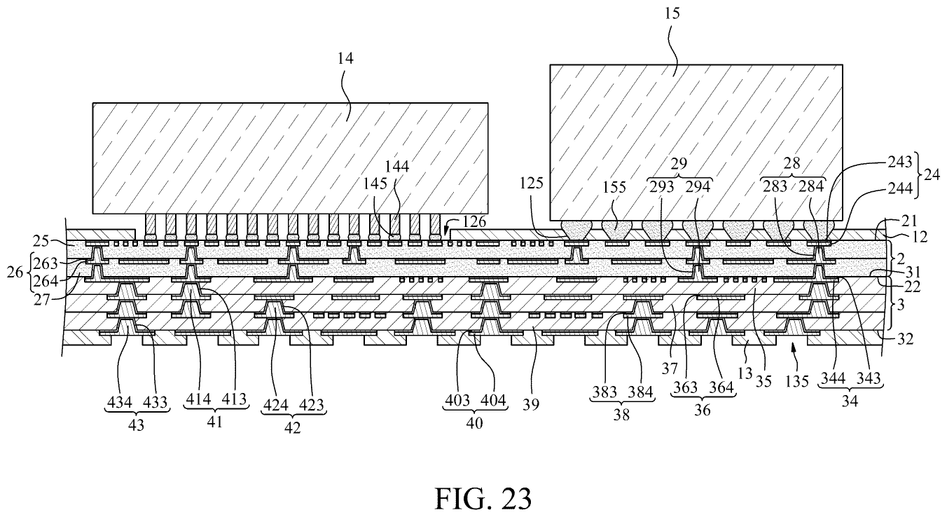

Referring to FIG. 23, a first electronic component 14 is disposed on and electrically connected to the first circuit layer 24 of the second circuit pattern structure 2 through the bumps 144 and the bonding materials 145. A second electronic component 15 is disposed on and electrically connected to the first circuit layer 24 of the second circuit pattern structure 2 through the bonding materials 155.

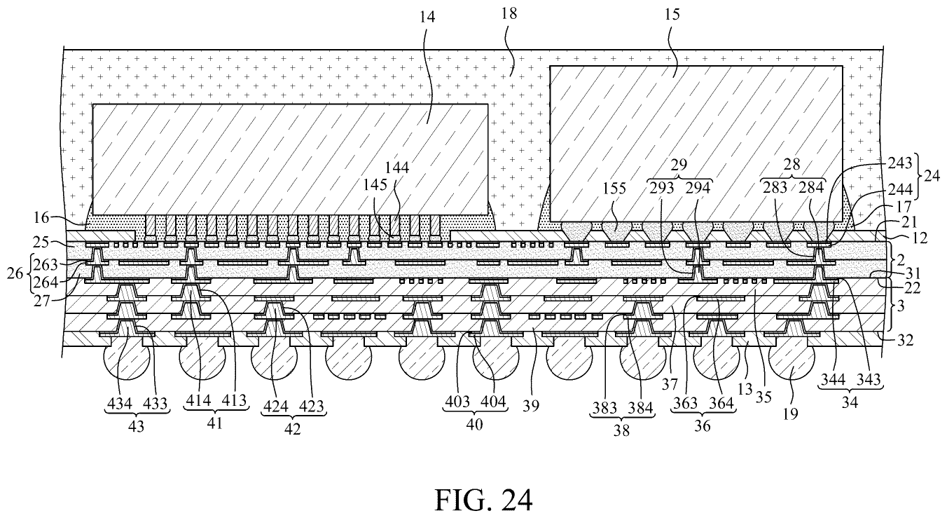

Referring to FIG. 24, a first underfill 16 is formed or disposed between the first electronic component 14 and the first surface 21 (e.g., the top surface) of the second circuit pattern structure 2. A second underfill 17 is formed or disposed between the second electronic component 15 and the top surface of the upper protection layer 12. An encapsulant 18 is formed to cover at least a portion of the first electronic component 14, at least a portion of the second electronic component 15, the first underfill 16, the second underfill 17 and the top surface of the upper protection layer 12. Then, a plurality of external connectors 19 are formed or disposed on the second surface 32 (e.g., the bottom surface) of the first circuit pattern structure 3 for external connection. The external connectors 19 are formed or disposed in the openings 135 and on the exposed portions (i.e., the exposed via portions) of the fourth circuit layer 40 of the first circuit pattern structure 3.

Then, a singulation process may be conducted to obtain at least one package structure of FIG. 1.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a substrate;
a redistribution layer (RDL) structure disposed on the substrate;
a first electronic component disposed over the redistribution layer (RDL) structure; and
a second electronic component disposed over the redistribution layer (RDL) structure,
wherein the first electronic component is electrically communicated with the second electronic component through the substrate and the redistribution layer (RDL) structure, wherein a number of input/output (I/O) count of the redistribution layer (RDL) structure is less than a number of input/output (I/O) count of the substrate.

2. The package structure of claim 1, wherein the substrate includes a first circuit layer and a second circuit layer, and the redistribution layer (RDL) structure includes a signal transmission layer, wherein a first number of input/output (I/O) count of the signal transmission layer is greater than a second number of input/output (I/O) count of the first circuit layer, the second number of input/output (I/O) count of the first circuit layer is greater than a third number of input/output (I/O) count of the second circuit layer.

3. The package structure of claim 2, wherein a signal transmission capacity of the signal transmission layer is greater than a signal transmission capacity of the first circuit layer and a signal transmission capacity of the second circuit layer.

4. The package structure of claim 3, wherein the signal transmission capacity of the first circuit layer is greater than a signal transmission capacity of the second circuit layer.

5. The package structure of claim 4, wherein a total signal transmission capacity is defined as a sum of the signal transmission capacity of the signal transmission layer of the second circuit pattern structure, the signal transmission capacity of the first circuit layer of the first circuit pattern structure and the signal transmission capacity of the second circuit layer of the first circuit pattern structure, wherein a first ratio of the signal transmission capacity of the signal transmission layer of the second circuit pattern structure to the total signal transmission capacity is about 40% to 50%, a second ratio of the signal transmission capacity of the first circuit layer of the first circuit pattern structure to the total signal transmission capacity is about 30% to 40%, a third ratio of the signal transmission capacity of the second circuit layer of the first circuit pattern structure to the total signal transmission capacity is about 20% to 30%.

6. The package structure of claim 2, wherein the first circuit layer is disposed between the signal transmission layer and the second circuit layer.

7. The package structure of claim 2, wherein the redistribution layer (RDL) structure further includes a first grounding layer disposed between the signal transmission layer and the first circuit layer.

8. The package structure of claim 2, wherein the substrate further includes a second grounding layer disposed between the first circuit layer and the second circuit layer.

9. The package structure of claim 1, wherein the second electronic component includes a first region, a second region and a third region, wherein the first region is closest to the first electronic component, and the second region is closer to the first electronic component than the third region is.

10. The package structure of claim 9, wherein the first electronic component includes a first region electrically connected to the first region, the second region and the third region of the second electronic component.

11. The package structure of claim 10, wherein an area of the first region of the first electronic component is less than an area of the first region, an area of the second region and an area of the third region of the second electronic component.

12. The package structure of claim 9, wherein the first region, the second region and the third region of the second electronic component do not overlap each other in a direction perpendicular to a top surface of the redistribution layer (RDL) structure.

13. A package structure, comprising:
a low-density conductive structure including a plurality of circuit layers and a plurality of inner vias electrically connecting the plurality of circuit layers;
a high-density conductive structure disposed on the low-density conductive structure, and including a plurality of circuit layers and a plurality of inner vias electrically connecting the plurality of circuit layers;
a first electronic component disposed over the high-density conductive structure; and
a second electronic component disposed over the high-density conductive structure and spaced apart from the first electronic component,
wherein the plurality of inner vias of the low-density conductive structure and the plurality of inner vias of the high-density conductive structure taper toward the first electronic component and the second electronic component.

14. The package structure of claim 13, wherein a line width/line space (L/S) of one of the plurality of circuit layers of the high-density conductive structure is less than an L/S of one of the plurality of circuit layers of the low-density conductive structure.

15. The package structure of claim 13, wherein a width of one of the plurality of inner vias of the low-density conductive structure is greater than a width of one of the plurality of inner vias of the high-density conductive structure.

16. A package structure, comprising:
a substrate including a first circuit layer and a second circuit layer;
a redistribution layer (RDL) structure disposed on the substrate, and including a signal transmission layer;
a first electronic component disposed over the signal transmission layer, wherein the first electronic component includes a first region; and
a second electronic component disposed over the signal transmission layer,
wherein the first region of the first electronic component is electrically connected to second electronic component by a first signal transmission path passing through the signal transmission layer, a second signal transmission path passing through the first circuit layer, and a third signal transmission path passing through the second circuit layer,
wherein an entire length of the first signal transmission path is shorter than an entire length of the second signal transmission path.

17. The package structure of claim 16, wherein the second electronic component includes a first region, a second region and a third region, wherein the first region is closest to the first electronic component, and the second region is closer to the first electronic component than the third region is, wherein the first region of the first electronic component is electrically connected to the first region, the second region and the third region of the second electronic component by the first signal transmission path, the second signal transmission path, and the third signal transmission path, respectively.

18. The package structure of claim 16, wherein the first signal transmission path, the second signal transmission path and the third signal transmission path overlap each other in a direction perpendicular to a top surface of the redistribution layer (RDL) structure.

19. The package structure of claim 16, wherein the first signal transmission path has a vertical portion and a horizontal portion, and the second signal transmission path has a vertical portion and a horizontal portion, wherein the horizontal portion of the second signal transmission path is longer than the horizontal portion of the first signal transmission path, and the vertical portion of the second signal transmission path is longer than the vertical portion of the first signal transmission path.

20. The package structure of claim 16, wherein a signal transmission capacity of the second signal transmission path is less than a signal transmission capacity of the first signal transmission path.
